(19) United States
(12) Patent Application Publication
(10) Pub. No.: US 2014/0102372 A1
(43) Pub. Date: Apr. 17, 2014

(54) WAFER CARRIER

(71) Applicant: EPISTAR CORPORATION, Hsinchu (TW)

(72) Inventors: Chung-Ying Chang, Hsinchu (TW); Yun-Ming Lo, Hsinchu (TW); Chi Shen, Hsinchu (TW); Ying-Chan Tseng, Hsinchu (TW)

(21) Appl. No.: 13/912,321

(22) Filed: Jun. 7, 2013

Related U.S. Application Data
(63) Continuation-in-part of application No. 13/649,445, filed on Oct. 11, 2012.

(51) Int. Cl. C30B 25/12

(52) U.S. Cl. CPC C30B 25/12
USPC 118/725

(57) ABSTRACT

A wafer carrier comprises a supporting body having a height and comprising an opening, wherein a bottom surface of the opening is a curved surface; and a plurality of supporting rods formed around a periphery of the supporting body. Another aspect of the present application provides a manufacturing method of the wafer carrier. The method comprises forming an epitaxial layer on a growth substrate to form a wafer structure; measuring a curvature radius of the wafer structure; and providing the wafer carrier described above in accordance with the curvature radius of the wafer structure.

### REFERENCE TO RELATED APPLICATION

The present application is a continuation-in-part application of U.S. patent application Ser. No. 13/649,445, filed on Oct. 11, 2012, now pending, and which claims the right of priority based on Taiwan Application Serial Number 100137510, filed Oct. 14, 2011, the disclosure of which is incorporated herein by reference in their entireties.

### TECHNICAL FIELD

The application relates to a wafer carrier, and more particularly, to a wafer carrier having a supporting body and a plurality of supporting rods formed around a periphery of the supporting body.

### DESCRIPTION OF BACKGROUND ART

In the manufacturing of a light-emitting diode (LED), an epitaxial layer is grown on a substrate. The substrate functions as a seed layer. When the lattice constant of the substrate is similar to the lattice constant of the epitaxial layer, a defect such as dislocation between the epitaxial layer and the substrate can be reduced. When the epitaxial layer is formed on the substrate, a stress is formed between the epitaxial layer and the substrate under different temperature regions of the reactor furnace. The stress affects the epitaxial quality of the epitaxial layer, and the stress may result in warp in the epitaxial layer. Thus, the material of the substrate is preferably similar to the material of the epitaxial layer. Because of the similar physical characteristics, such as the lattice constant, of the substrate and the epitaxial layer, the stress can be reduced. However, for some epitaxial layers, there is no suitable substrate available for use, neither the same material as the epitaxial layer, nor the same lattice constant as the epitaxial layer. Further, in consideration of the cost of the production, there may be no suitable substrate available.

Based on the reasons described above, once the material of the substrate and the material of the epitaxial layer are different, one or more materials of the epitaxial layer is different from the material of the substrate when the epitaxial layer is composed of a plurality of materials, or the lattice constant, the thermal expansion coefficient or the hardness of the epitaxial layer is different from that of the substrate, which results in different degrees of stress between the substrate and the epitaxial layer at different temperatures of the reactor furnace when the epitaxial layer is formed on the substrate. The stress may result in different degrees of curvature or warp. Mild stress may result in uneven heating of the epitaxial layer, which further results in poor epitaxial quality. The bending caused by the epitaxial layer warp also impacts the following process. However, if the stress is too large, the epitaxial layer may rupture.

The growth method of the epitaxial layer of the light emitting diode comprises vapor phase epitaxy (VPE) or metal organic chemical vapor deposition (MOCVD). The metal organic chemical vapor deposition (MOCVD) method is most commonly used to grow the epitaxial layer, such as GaN or AlGaInP. First, a substrate is disposed on a wafer carrier. After that, an epitaxial layer is formed on the substrate to form a wafer structure in a reactor furnace. The temperature of the reactor furnace changes continually during the formation of the epitaxial layer. Because the lattice constants or the thermal expansion coefficients of the epitaxial layer and the substrate are different from each other, the wafer structure has different degrees of curvature or warp in different temperature regions.

When the wafer structure is bowed, the wafer cannot contact with the wafer carrier closely, which results in uneven temperature distribution across the whole wafer surface. If the light-emitting layer is grown on the wafer, the light-emitting wavelength distribution range across the whole wafer is large.

FIG. 1 illustrates a conventional wafer carrier 10. The wafer carrier 10 comprises a carrier body 100 having an opening 102. A bottom surface 103 of the opening 102 is a flat surface. A wafer 104 comprises a growth substrate and an epitaxial layer grown on the growth substrate, and the epitaxial layer comprises a light-emitting layer. When the epitaxial layer is grown on the growth substrate, the furnace temperature is changed continually. Due to the lattice constants and the thermal expansion coefficients of the epitaxial layer and the growth substrate are different from each other, different degrees of curvature and warp are produced on the wafer in different temperature regions. As shown in FIG. 1, the wafer 104 is convex warp in a cross-sectional view. When the light-emitting layer is grown on the growth substrate, only partial surface of the wafer 104 is contacted with the bottom surface 103 of the opening 102 of the wafer carrier 10. When the reactor furnace temperature for the growth of the light emitting layer is set at a value by considering the condition of the center area of the wafer 104, the growth temperature of the edge of the wafer 104 is different from the growth temperature of the center of the wafer 104. Because the growth temperature varies with different regions of the wafer 104, the light-emitting wavelengths of different regions of the wafer 104 are also different.

FIG. 2 illustrates a conventional wafer carrier 20. The wafer carrier 20 comprises a carrier body 200 having an opening 202. A bottom surface 203 of the opening 202 is a flat surface. A wafer 204 comprises a growth substrate and an epitaxial layer grown on the growth substrate, and the epitaxial layer comprises a light-emitting layer. As illustrated in FIG. 2, the wafer 204 is concave warp in a cross-sectional view. When the light-emitting layer is grown on the growth substrate, only partial surface of the wafer 204 is contacted with the bottom surface 203 of the opening 202 of the wafer carrier 20. The wafer 204 is shaken easily and may fly out when the wafer carrier 20 is rotated at high speed.

FIG. 3A illustrates a conventional wafer carrier 30. The wafer carrier 30 comprises a carrier body 300 having an opening 302, wherein a bottom surface 303 of the opening 302 is a flat surface; and a supporting ring 305 provided around a periphery of the carrier body 300. A wafer 304 comprises a growth substrate and an epitaxial layer grown on the growth substrate, and the epitaxial layer comprises a light-emitting layer.

FIG. 3B illustrates a top view of the conventional wafer carrier 30. As illustrated in FIG. 3B, the top view of the supporting ring 305 is approximately a circular shape. The supporting ring 305 supports the wafer 304 around a periphery of the wafer 304 and the wafer 304 is not shaken easily. But the temperature of the wafer periphery contacted directly with the supporting ring 305 and the temperature of the wafer center not directly contacted with the supporting ring 305 are different, which results in different growth temperatures in different regions of the wafer 304 when the light-emitting layer is grown on the growth substrate.

### SUMMARY OF THE APPLICATION

A wafer carrier comprises a supporting body having a height and comprising an opening, wherein a bottom surface of the opening is a curved surface; and a plurality of supporting rods formed around a periphery of the supporting body. Another aspect of the present application provides a manufacturing method of the wafer carrier. The method comprises forming an epitaxial layer on a growth substrate to form a wafer structure; measuring a curvature radius of the wafer structure; and providing the wafer carrier described above in accordance with the curvature radius of the wafer structure.

### BRIEF DESCRIPTION OF THE DRAWINGS

FIG. 1 illustrates a cross-sectional view of a conventional wafer carrier;

FIG. 2 illustrates a cross-sectional view of a conventional wafer carrier;

FIG. 3A illustrates a cross-sectional view of a conventional wafer carrier;

FIG. 3B illustrates a top view of a conventional wafer carrier;

FIG. 4A illustrates a cross-sectional view of a wafer carrier in accordance with a first embodiment of the present application;

FIG. 4B illustrates a top view of a wafer in accordance with a first embodiment of the present application;

FIG. 5A illustrates a cross-sectional view of a wafer carrier in accordance with a second embodiment of the present application;

FIG. 5B illustrates a top view of a wafer in accordance with a second embodiment of the present application;

FIG. 6 illustrates a top view of a wafer carrier in accordance with an embodiment of the present application;

FIG. 7 illustrates a top view of each supporting rod of a wafer carrier in accordance with an embodiment of the present application;

FIG. 7A illustrates a top view of a wafer carrier in accordance with an embodiment of the present application;

FIG. 8A illustrates a top view of a wafer carrier comprising a flat edge in accordance with an embodiment of the present application;

FIG. 8B illustrates a top view of a wafer and a wafer carrier in accordance with an embodiment of the present application;

FIG. 9 illustrates a top view of a susceptor in accordance with an embodiment of the present application; and

FIG. 10 illustrates a top view of a heater in accordance with an embodiment of the present application.

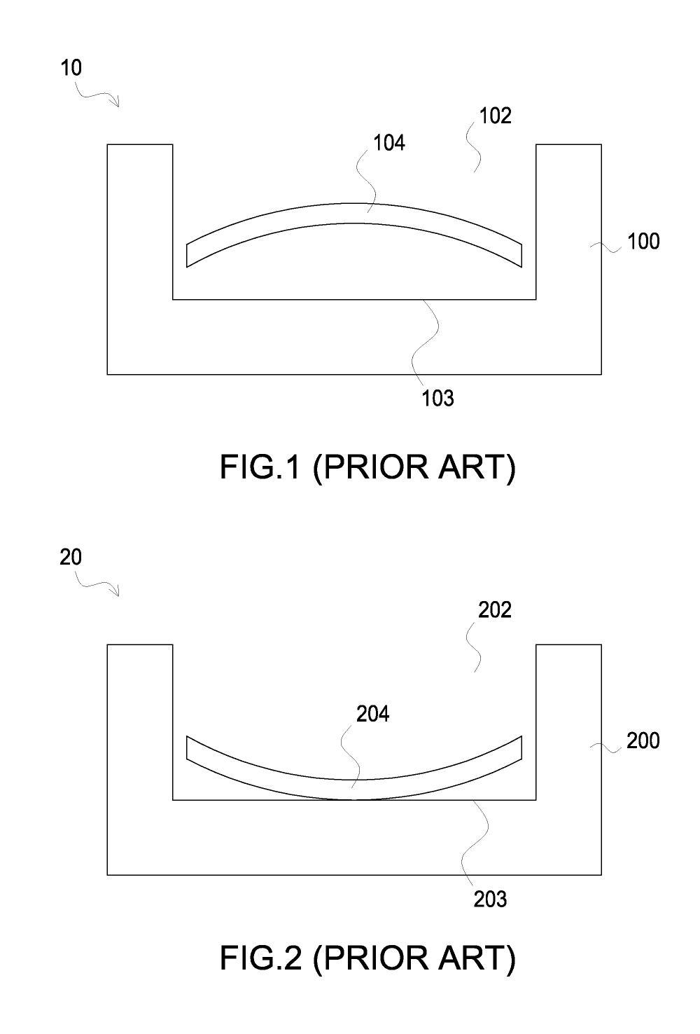

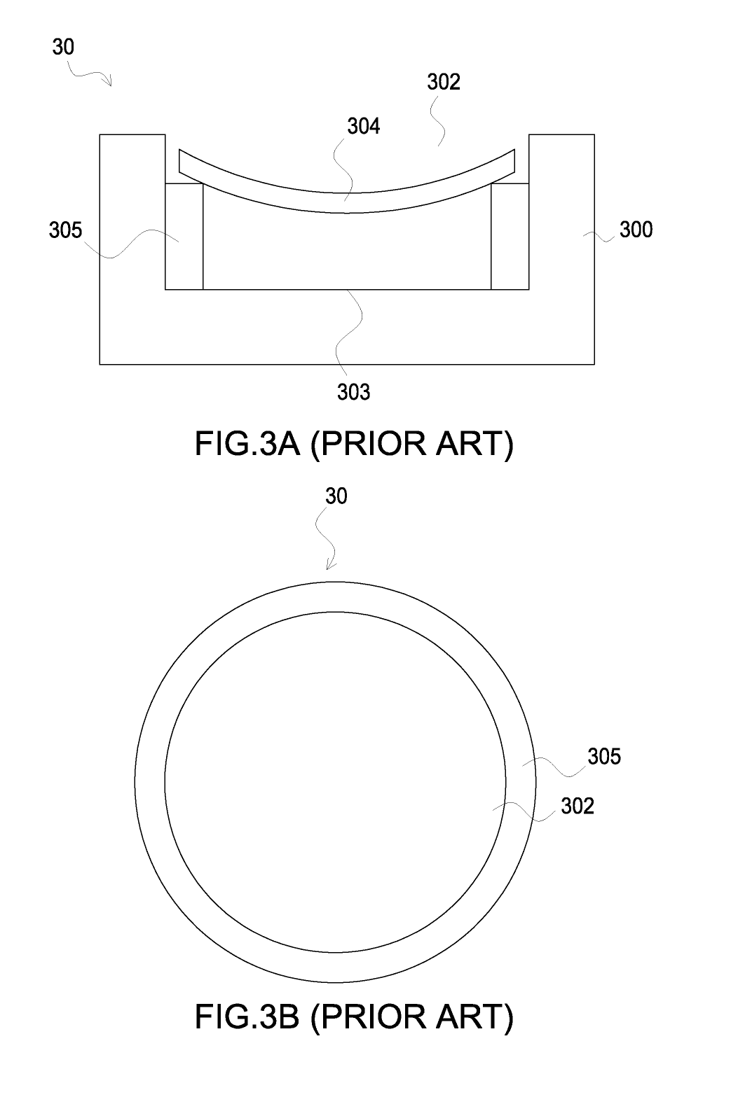

### DETAILED DESCRIPTION OF PREFERRED EMBODIMENTS

The embodiment of the application is illustrated in detail, and is plotted in the drawings. The same or the similar part is illustrated in the drawings and the specification with the same number.

It should be noted that an expression of an element or a material layer being formed or connected to another element or another material layer comprises the element or the material layer being directly or indirectly formed or connected to another element or another material layer, that is to say other elements or material layers can be formed there between. If the present application describes an element or a material layer being directly formed or connected to another element or material layer, that is to say no other elements or material layers are formed there between.

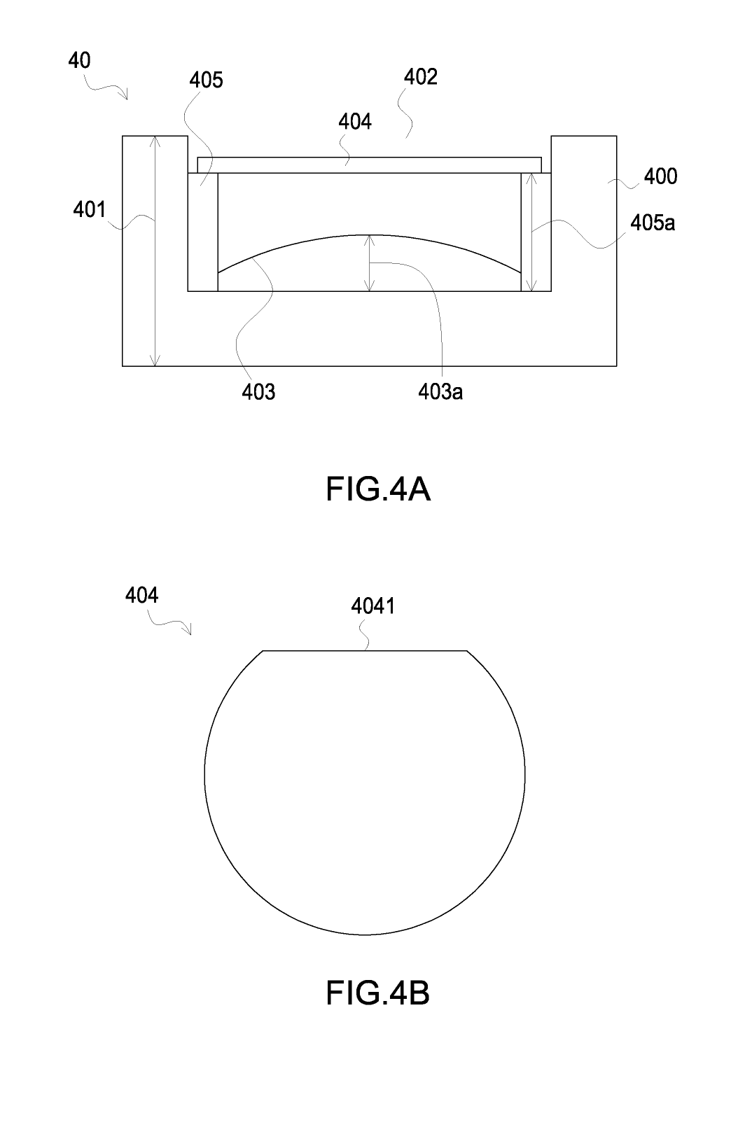

FIG. 4A illustrates a cross-sectional view of a wafer carrier 40 in accordance with a first embodiment of the present application. As shown in FIG. 4A, the wafer carrier 40 comprises a supporting body 400 having a height 401; and a plurality of supporting rods 405, formed around a periphery of the supporting body 400. The supporting body 400 comprises an opening 402, wherein a bottom surface 403 of the opening 402 is a curved surface.

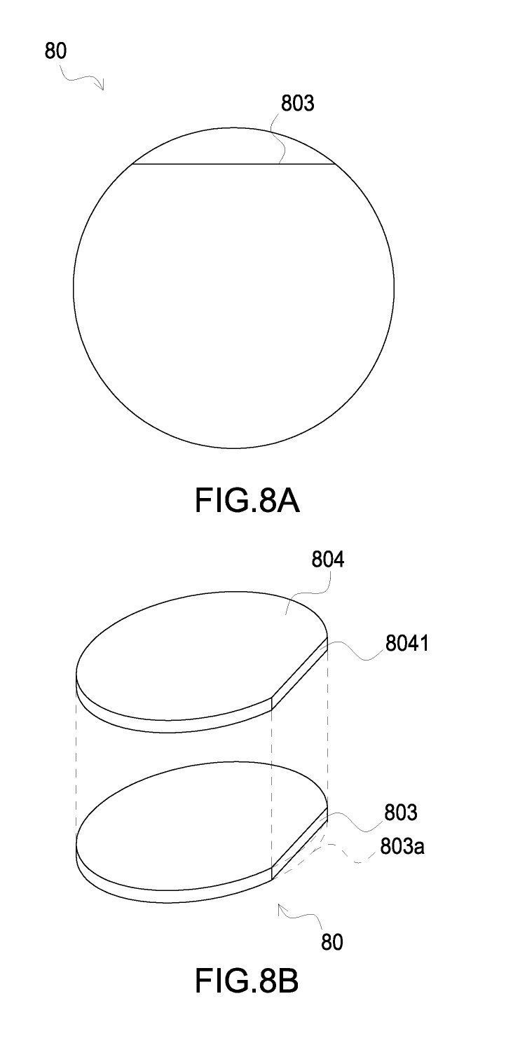

A top view of the opening 402 of the wafer carrier 40 is approximately a circle shape. The opening 402 can accommodate a commercial wafer having a diameter between 2 in and 8 in. The top view of the wafer carrier 40 can be referred to FIG. 8A. FIG. 8A illustrates a top view of a wafer carrier 80 in accordance with an embodiment of the present application. If the wafer carrier 80 is used to support a wafer having a diameter of 4 in or above, the top view of the opening (not shown) of the wafer carrier 80 further comprises a flat edge 803. As shown in FIG. 4A, a wafer 404 comprises a growth substrate and an epitaxial layer formed on the growth substrate, and the epitaxial layer comprises a light-emitting layer. The material of the epitaxial layer comprises an element selected from a group consisting of Gallium (Ga), aluminum (Al), indium (In), phosphorus (P), nitrogen (N), zinc (Zn), arsenic (As), cadmium (Cd) and selenium (Se).

The material of the supporting body 400 comprises composite material, such as ceramic material; semiconductor material, such as boron nitride (BN) or silicon carbide (SiC); conductive material, such as graphite or metal, wherein the metal comprises molybdenum (Mo), tungsten (W), titanium (Ti), zirconium (Zr) or the combination thereof; or non-conductive material, such as quartz.

In accordance with the first embodiment of the present application, the top view of the opening 402 is approximately a circle shape, wherein the top view of the opening 402 comprises a side and a center. The side is an edge of the opening 402. The bottom surface 403 of the opening 402 is a curved surface and the curved surface is a convex surface, wherein the center of the opening 402 has a height 403a protruding from the side of the opening 402. The height 403a of the convex surface can be between 15 μm and 1000 μm. The height 403a of the convex surface is proportional to the diameter of the wafer 404 supported by the wafer carrier 40, and a ratio between the diameter of the wafer 404 and the height 403a of the convex surface is between 7 and 125. When the epitaxial layer is formed on the growth substrate to form the wafer 404 at high temperature, the wafer 404 is bowed easily. The larger the diameter of the wafer 404 is, the more easily bowed the wafer 404 is. Thus, the height 403a of the convex surface is increased accompanied with the increase of the diameter of the wafer 404. In an embodiment, the diameter of the wafer 404 is 2 in, and the height 403a of the convex surface of the supporting body 400 can be between 15 μm and 65 μm. In another embodiment, the diameter of the wafer 404 is 4 in, and the height 403a of the convex surface of the supporting body 400 can be between 15 μm and 160 μm. In another embodiment, the diameter of the wafer 404 is 6 in, the height 403a of the convex surface of the supporting body 400 can be between 15 μm and 400 μm. In another embodiment, the diameter of the wafer 404 is 8 in, the height 403a of the convex surface of the supporting body 400 can be between 15 μm and 1000 μm.

Because the lattice constants or the thermal expansion coefficients of the epitaxial layer and the growth substrate are different from each other, the warp degree and the warp shape of the wafer are different in different temperature regions. When the warp shape of the wafer is a convex surface, the wafer carrier 40 having the convex surface is preferably provided, which results in more even temperature distribution across the wafer surface, and more even distribution of the light-emitting wavelength of the light-emitting layer across the whole wafer.

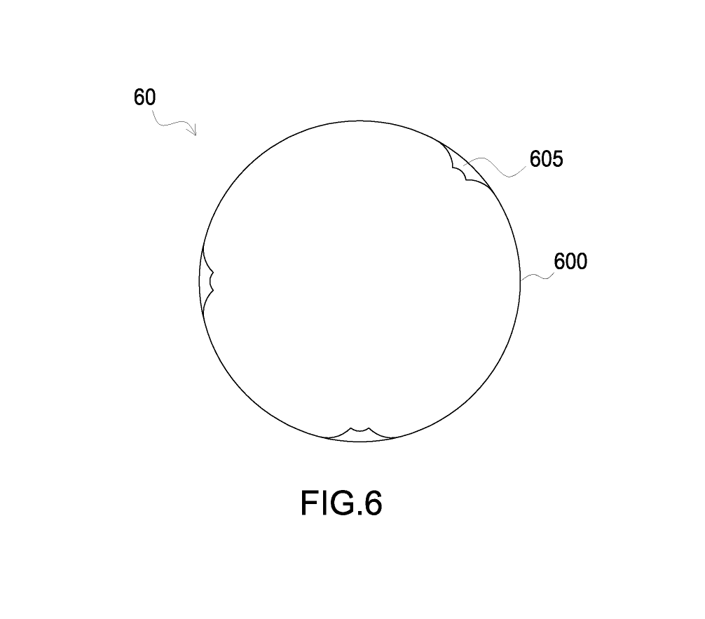

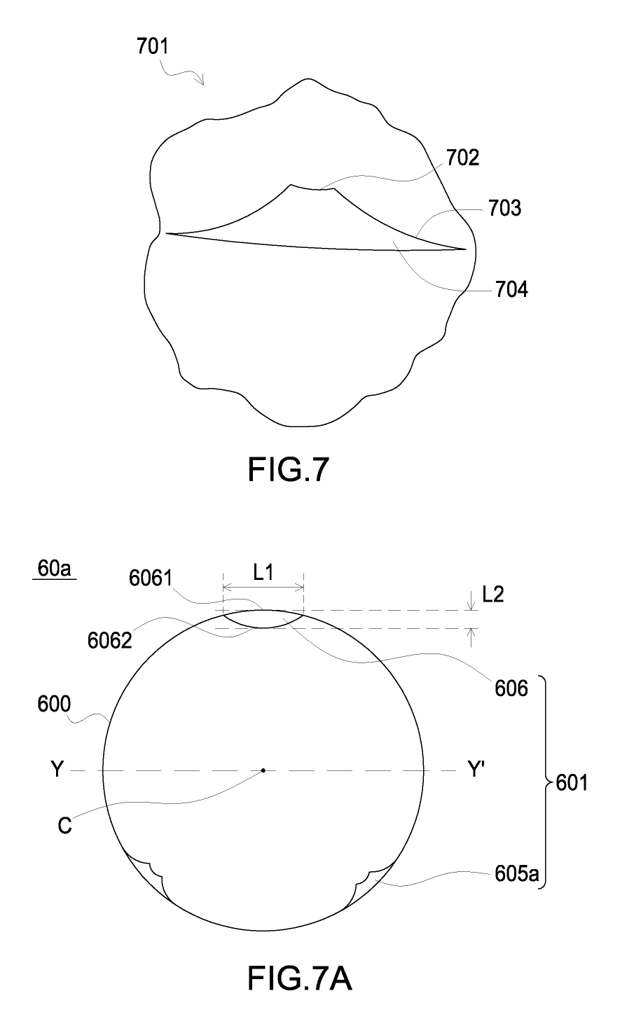

In accordance with the first embodiment of the present application, the wafer carrier 40 further comprises the plurality of supporting rods 405 formed around the periphery of the supporting body 400. In the embodiment, there are at least three supporting rods 405. The top view of the plurality of supporting rods 405 formed around the periphery of the supporting body 400 can be referred to FIG. 6 or FIG. 7A. FIG. 6 illustrates a top view of a wafer carrier 60 in accordance with an embodiment of the present application. As illustrated in FIG. 6, there are at least three supporting rods 605, and the plurality of supporting rods 605 is formed around the periphery of the supporting body 600. The plurality of supporting parts 605 is located unevenly along a perimeter of the wafer carrier 60. Specifically, more than half of the supporting rods 605 is located on one part of the perimeter of the wafer carrier 60, and less than half of the supporting rods 605 is located on another part of the perimeter of the wafer carrier 60 when an imaginary line is depicted through a center of the wafer carrier 60.

A top view of each supporting rod 405 can be referred to FIG. 7. FIG. 7 illustrates a top view of each supporting rod 704 of a wafer carrier 701 in accordance with an embodiment of the present application. Each supporting rod 704 comprises a first side 702 and a plurality of second sides 703, wherein the first side 702 comprises a first arc surface having a first curvature radius, and each of the plurality of second sides 703 comprises a second arc surface having a second curvature radius, wherein the second curvature radius is not equal to the first curvature radius.

FIG. 7A illustrates a top view of a wafer carrier 60a in accordance with another embodiment of the present application. The wafer carrier 60a comprises a supporting body 600 and a plurality of supporting rods 601 formed around the periphery of the supporting body 600. The plurality of supporting rods 601 comprises a first supporting rod 606 and a second supporting rod 605a. In the embodiment, one or more supporting rods 605 shown in FIG. 6 are replaced by the first supporting rod 606. The first supporting rod 606 has a feature size larger than that of the second supporting rod 605a. The feature size comprises a top-viewed surface. Specifically, the first supporting rod 606 has a top-viewed surface area larger than that of the second supporting rod 605a. The second supporting rod 605a comprises a shape or a size same as the supporting rods 605 shown in FIG. 6 or the supporting rod 704 shown in FIG. 7. The first supporting rod 606 comprises a third side 6062 and a fourth side 6061, wherein the third side 6062 is closer to a center C of the wafer carrier 60a than the fourth side 6061 in a top view of the wafer carrier 60a. The third side 6062 comprises a third arc surface having a third curvature radius and the fourth side 6061 comprises a fourth arc surface having a fourth curvature radius. Compared with the supporting rod 704 shown in FIG. 7, the third side 6062 has a feature size, such as the third curvature radius, different from the first curvature radius of the first side 702 or the second curvature radius of the second side 703. The third side 6062 and the fourth side 6061 are connected at two opposite terminals. In an example of the embodiment, a distance L1 between the two opposite terminals is 15%˜50% of a diameter of the wafer carrier 60a. A maximum distance L2 between the third arc surface and the fourth arc surface is 1%˜30% of a diameter of the wafer carrier 60a.

When an imaginary line Y-Y′ is depicted through a center of the wafer carrier 60a, more than half of the plurality of supporting rods 601 is formed on one part of the perimeter of the wafer carrier 60a, such as a part below line Y-Y′, and less than half of the plurality of supporting rods 601 is formed on another part of the perimeter of the wafer carrier 40b, such as a part above line Y-Y′.

As illustrated in FIG. 4A, each of the plurality of supporting rods 405 comprises a height 405a smaller than the height 401 of the supporting body 400. The height 405a of each of the plurality of supporting rods 405 is larger than the height 403a of the convex surface of the supporting body 400. The height 405a of the supporting rod 405 can be between 15 μm and 1000 μm. The material of the plurality of supporting rods 405 comprises composite material, such as ceramic material; semiconductor material, such as boron nitride (BN) or silicon carbide (SiC); conductive material, such as graphite or metal, wherein the metal comprises molybdenum (Mo), tungsten (W), titanium (Ti), zirconium (Zr) or the combination thereof; or non-conductive material, such as quartz.

FIG. 4B illustrates a top view of the wafer 404 in accordance with an embodiment of the present application. The wafer 404 comprises a flat edge 4041. As illustrated in FIG. 4A, after the wafer 404 is supported by the plurality of supporting rods 405, the wafer 404 cannot directly contact with the bottom surface 403 of the wafer carrier 40. Thus, it is not easy to heat the wafer 404, especially the flat edge 4041, and that impacts the light-emitting wavelength emitted from the light-emitting layer of the wafer 404. This phenomenon is more pronounced accompanied with increasing the diameter of the wafer 404. FIG. 8A illustrates the top view of the wafer carrier 80 comprising the flat edge 803. FIG. 8B illustrates the top view of the wafer carrier 80 comprising the flat edge 803 and the wafer 804 comprising a flat edge 8041. As illustrated in FIG. 8A and FIG. 8B, when the wafer carrier 80 comprises the flat edge 803, a gap 803a between a flat edge 8041 of a wafer 804 and the flat edge 803 of the wafer carrier 80 is reduced, and that improves the heating uniformity. In accordance with the embodiment illustrated in FIG. 8B, when the wafer carrier 40 is used to support the wafer 404 having a diameter of 4 in or above and the flat edge 4041, the wafer carrier 40 preferably comprises a flat edge.

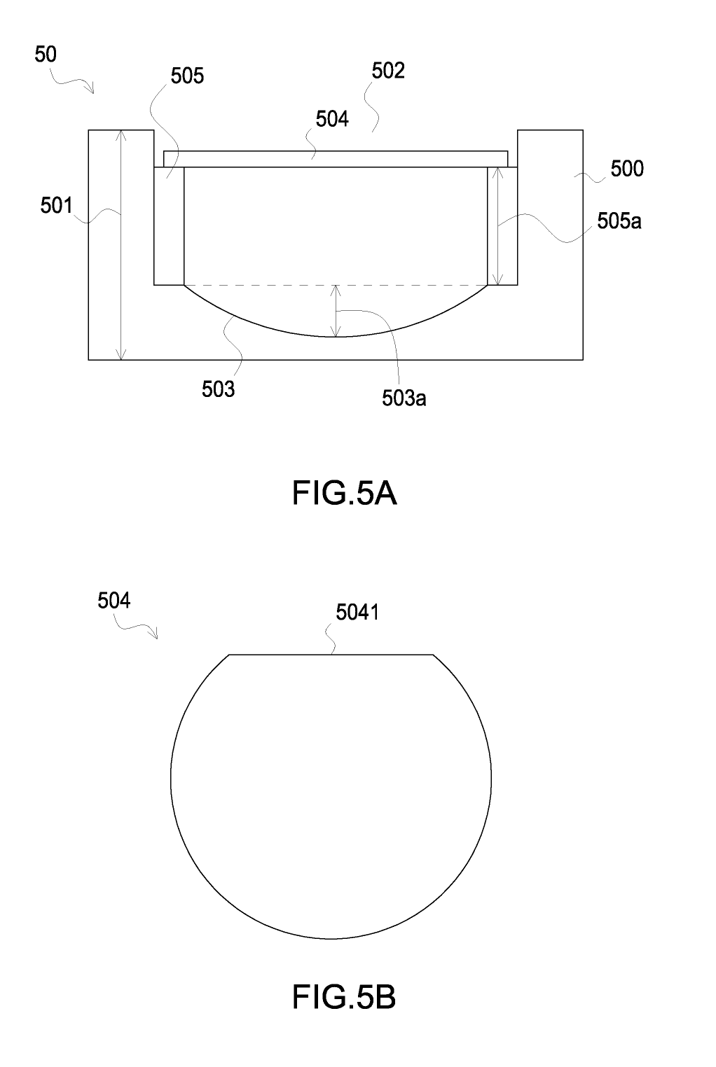

FIG. 5A illustrates a cross-sectional view of a wafer carrier 50 in accordance with a second embodiment of the present application. As shown in FIG. 5A, the wafer carrier 50 comprises a supporting body 500 having a height 501; and a plurality of supporting rods 505 formed around a periphery of the supporting body 500. The supporting body 500 comprises an opening 502, wherein a bottom surface 503 of the opening 502 is a curved surface.

A top view of the opening 502 of the wafer carrier 50 is approximately a circle shape. The opening 502 can accommodate a commercial wafer having a diameter between 2 in and 8 in. The top view of the wafer carrier 50 can be referred to FIG. 8A. FIG. 8A illustrates a top view of a wafer carrier 80 in accordance with an embodiment of the present application. If the wafer carrier 80 is used to support a wafer having a diameter of 4 in or above, the top view of the opening (not shown) of the wafer carrier 80 further comprises a flat edge 803. As shown in FIG. 5A, a wafer 504 comprises a growth substrate and an epitaxial layer formed on the growth substrate, wherein the epitaxial layer comprises a light-emitting layer. The material of the epitaxial layer comprises an element selected from a group consisting of Gallium (Ga), aluminum (Al), indium (In), phosphorus (P), nitrogen (N), zinc (Zn), arsenic (As), cadmium (Cd) and selenium (Se).

The material of the supporting body 500 comprises composite material, such as ceramic material; semiconductor material, such as boron nitride (BN) or silicon carbide (SiC); conductive material, such as graphite or metal, wherein the metal comprises molybdenum (Mo), tungsten (W), titanium (Ti), zirconium (Zr) or the combination thereof; or non-conductive material, such as quartz.

In accordance with the second embodiment of the present application, the top view of the opening 502 is approximately a circle shape, wherein the top view of the opening 502 comprises a side and a center. The side is an edge of the opening 502. The bottom surface 503 of the opening 502 is a curved surface and the curved surface is a concave surface, wherein the center of the opening 502 has a depth 503a sinking from the side of the opening 502. The depth 503a of the concave surface can be between 15 μm and 1000 μm. The depth 503a of the concave surface is proportional to the diameter of the wafer 504 supported by the wafer carrier 50, and a ratio between the diameter of the wafer 504 and the depth 503a of the concave surface is between 7 and 125. When the epitaxial layer is formed on the growth substrate to form the wafer 504 at high temperature, the wafer 504 is bowed easily. The larger the diameter of the wafer 504 is, the more easily bowed the wafer 504 is. Thus, the depth 503a of the concave surface is increased accompanied with the increase of the diameter of the wafer 504. In the embodiment, the diameter of the wafer 504 is 2 in, and the depth 503a of the concave surface of the supporting body 500 can be between 15 μm and 65 μm. In another embodiment, the diameter of the wafer 504 is 4 in, and the depth 503a of the concave surface of the supporting body 500 can be between 15 μm and 160 μm. In another embodiment, the diameter of the wafer 504 is 6 in, and the depth 503a of the concave surface of the supporting body 500 can be between 15 μm and 400 μm. If the diameter of the wafer 504 is 8 in, the depth 503a of the concave surface of the supporting body 500 can be between 15 μm and 1000 μm.

Because the lattice constants or the thermal expansion coefficients of the epitaxial layer and the growth substrate are different from each other, the warp degree and the warp shape of the wafer are different in different temperature regions. When the bow shape of the wafer is a concave surface, the wafer carrier 50 having the concave surface is preferably provided, which results in more even temperature distribution across the wafer surface, and more even distribution of the light-emitting wavelength of the light-emitting layer across the whole wafer.

In accordance with the second embodiment of the present application, the wafer carrier 50 further comprises the plurality of supporting rods 505 formed around the periphery of the supporting body 500. In the embodiment, there are at least three supporting rods 505. The top view of the plurality of supporting rods 505 formed around the periphery of the supporting body 500 can be referred to FIG. 6 or FIG. 7A. FIG. 6 illustrates a top view of a wafer carrier 60 in accordance with an embodiment of the present application. As illustrated in FIG. 6, there are at least three supporting rods 605, and the plurality of supporting rods 605 is formed around the periphery of the supporting body 600. The plurality of supporting parts 605 is located unevenly along a perimeter of the wafer carrier 60. Specifically, more than half of the supporting rods 605 is located on one part of the perimeter of the wafer carrier 60, and less than half of the supporting rods 605 is located on another part of the perimeter of the wafer carrier 60 when an imaginary line is depicted through a center of the wafer carrier 60.

A top view of each supporting rod 505 can be referred to FIG. 7. FIG. 7 illustrates a top view of each supporting rod 704 of a wafer carrier 701 in accordance with an embodiment of the present application. Each supporting rod 704 comprises a first side 702 and a plurality of second sides 703, wherein the first side 702 comprises a first arc surface having a first curvature radius, and each of the plurality of second sides 703 comprises a second arc surface having a second curvature radius, wherein the second curvature radius is not equal to the first curvature radius.

FIG. 7A illustrates a top view of a wafer carrier 60a in accordance with another embodiment of the present application. The wafer carrier 60a comprises a supporting body 600 and a plurality of supporting rods 601 formed around the periphery of the supporting body 600. The plurality of supporting rods 601 comprises a first supporting rod 606 and a second supporting rod 605a. In the embodiment, one or more supporting rods 605 shown in FIG. 6 are replaced by the first supporting rod 606. The first supporting rod 606 has a feature size larger than that of the second supporting rod 605a. The feature size comprises a top-viewed surface. Specifically, the first supporting rod 606 has a top-viewed surface area larger than that of the second supporting rod 605a. The second supporting rod 605a comprises a shape or a size same as the supporting rods 605 shown in FIG. 6 or the supporting rod 704 shown in FIG. 7. The first supporting rod 606 comprises a third side 6062 and a fourth side 6061, wherein the third side 6062 is closer to a center C of the wafer carrier 60a than the fourth side 6061 in a top view of the wafer carrier 60a. The third side 6062 comprises a third arc surface having a third curvature radius and the fourth side 6061 comprises a fourth arc surface having a fourth curvature radius. Compared with the supporting rod 704 shown in FIG. 7, the third side 6062 has a feature size, such as the third curvature radius, different from the first curvature radius of the first side 702 or the second curvature radius of the second side 703. The third side 6062 and the fourth side 6061 are connected at two opposite terminals. In an example of the embodiment, a distance L1 between the two opposite terminals is 15%˜50% of a diameter of the wafer carrier 60a. A distance L2 between an apex of the third arc surface and an apex of the fourth arc surface is 1%˜30% of a diameter of the wafer carrier 60a.

When an imaginary line Y-Y′ is depicted through a center of the wafer carrier 60a, more than half of the plurality of supporting rods 601 is located on one part of the perimeter of the wafer carrier 60a, such as a part below line Y-Y′, and less than half of the plurality of supporting rods 601 is located on another part of the perimeter of the wafer carrier 40b, such as a part above line Y-Y′.

As illustrated in FIG. 5A, each of the plurality of supporting rods 505 comprises a height 505a smaller than the height 501 of the supporting body 500. The height 505a of each of the plurality of supporting rods 505 is larger than the depth 503a of the concave surface of the supporting body 500. The height 505a of the supporting rod 505 can be between 15 μm and 1000 μm. The material of the plurality of supporting rods 505 comprises composite material, such as ceramic material; semiconductor material, such as boron nitride (BN) or silicon carbide (SiC); conductive material, such as graphite or metal, wherein the metal comprises molybdenum (Mo), tungsten (W), titanium (Ti), zirconium (Zr) or the combination thereof; or non-conductive material, such as quartz.

FIG. 5B illustrates a top view of the wafer 504 in accordance with an embodiment of the present application. The wafer 504 comprises a flat edge 5041. As illustrated in FIG. 5A, after the wafer 504 is supported by the plurality of supporting rods 505, the wafer 504 cannot directly contact with the bottom surface 503 of the wafer carrier 50. Thus, it is not easy to heat the wafer 504, especially the flat edge 5041, and that impacts the light-emitting wavelength emitted from the light-emitting layer of the wafer 504. This phenomenon is more pronounced accompanied with an increase of the diameter of the wafer 504. FIG. 8A illustrates the top view of the wafer carrier 80 comprising the flat edge 803. FIG. 8B illustrates the top view of the wafer carrier 80 comprising the flat edge 803 and the wafer 804 comprising a flat edge 8041. As illustrated in FIG. 8A and FIG. 8B, when the wafer carrier 80 comprises the flat edge 803, a gap 803a between a flat edge 8041 of a wafer 804 and the flat edge 803 of the wafer carrier 80 is reduced, and the heating uniformity is improved. In the embodiment illustrated in FIG. 8B, when the wafer carrier 50 is used to support the wafer 504 having a diameter of 4 in or above and the flat edge 5041, the wafer carrier 50 preferably comprises a flat edge.

A manufacturing method of a wafer carrier is provided in accordance with an embodiment of the present application. The method comprises forming an epitaxial layer on a growth substrate to form a wafer structure; measuring a curvature radius of the wafer structure; and providing the wafer carrier as illustrated in the first embodiment or the second embodiment in accordance with the curvature radius of the wafer structure. When the warp shape of the wafer structure is a convex shape, a wafer carrier comprising a convex surface and a plurality of supporting rods is preferably provided, wherein the convex surface comprises a height and the range of the height can be referred to the first embodiment of the present application. When the warp shape of the wafer structure is a concave shape, a wafer carrier comprising a concave surface and a plurality of supporting rods is preferably provided, wherein the concave surface comprises a depth and the range of the depth can be referred to the second embodiment of the present application. The height of the convex surface and/or the depth of the concave surface are proportional to the diameter of the wafer. There are at least three supporting rods. The material of the epitaxial layer comprises an element selected from a group consisting of Gallium (Ga), aluminum (Al), indium (In), phosphorus (P), nitrogen (N), zinc (Zn), cadmium (Cd) and selenium (Se).

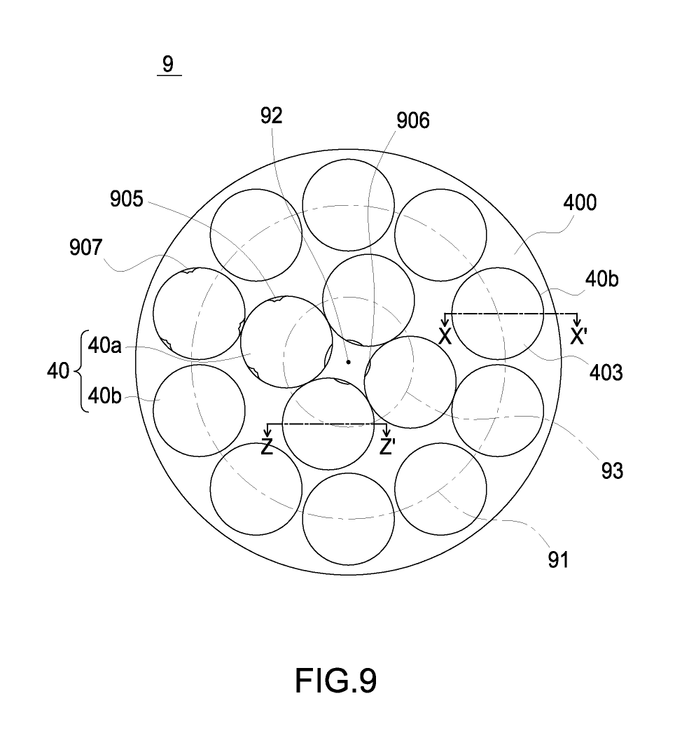

An apparatus for depositing a thin film comprises a susceptor and a heater. FIG. 9 illustrates a top view of a susceptor 9 in accordance with an embodiment of the present application. The susceptor 9 comprises a first top surface 400 having a first center 92 and a substantially flat bottom surface. A first group of wafer carriers 40a which surrounds the first center 92 and a second group of wafer carriers 40b which surrounds the first group of wafer carriers 40a are provided on the first top surface 400. The first group of wafer carriers 40a and the second group of wafer carriers 40b are arranged substantially concentric. Specifically, the first group of wafer carriers 40a forms an inner ring 93, the second group of wafer carriers 40b forms an outer ring 91, the inner ring 93 and the outer ring 91 are concentric circles, and the outer ring 91 has a diameter larger than a diameter of the inner ring 93. One or more commercial wafers can be disposed in the wafer carriers 40a or wafer carriers 40b for thin film deposition. The wafer carrier 40b or the wafer carrier 40a comprises the same cross-sectional view along line X-X′ of the wafer carrier 40b or Z-Z′ of the wafer carrier 40a as that illustrated in FIG. 4A or FIG. 5A.

One of the first group of wafer carriers 40a comprises a first supporting part 906 and a second supporting part 905. In an example of the embodiment, one of the first group of wafer carriers 40a comprises a plurality of the second supporting parts 905. The first supporting part 906 comprises a top view same as the supporting rod 606 shown in FIG. 7A, the second supporting part 905 comprises a top view same as the supporting rod 605 shown in FIG. 6 or the second supporting rod 605a shown in FIG. 7A. The first supporting part 906 has a feature size, such as a surface area, larger than that of the second supporting part 905. The first supporting part 906 is closer to the first center 92 of the first top surface 400 than the second supporting part 905. The first supporting part 906 is next to the first center 92. Specifically, the first supporting part 906 is located at a location having a minimum distance between one of the first group of the wafer carrier 40a and the first center 92.

One of the second group of wafer carriers 40b comprises a plurality of third supporting parts 907. The third supporting part 907 comprises a top view same as the supporting rod 605 shown in FIG. 6 or the second supporting rod 605a shown in FIG. 7A. The plurality of third supporting parts 907 is located unevenly along a perimeter of the wafer carrier 40b. Specifically, more than half of the plurality of third supporting part 907 is located on one part of the perimeter of the wafer carrier 40b, and less than half of the plurality of third supporting part 907 is located on another part of the perimeter of the wafer carrier 40b when an imaginary line is depicted through a center of the wafer carrier 40b.

An amount of the plurality of third supporting parts 907 in one of the second group of wafer carriers 40b is larger than an amount of the plurality of second supporting parts 905 in one of the first group of wafer carriers 40a.

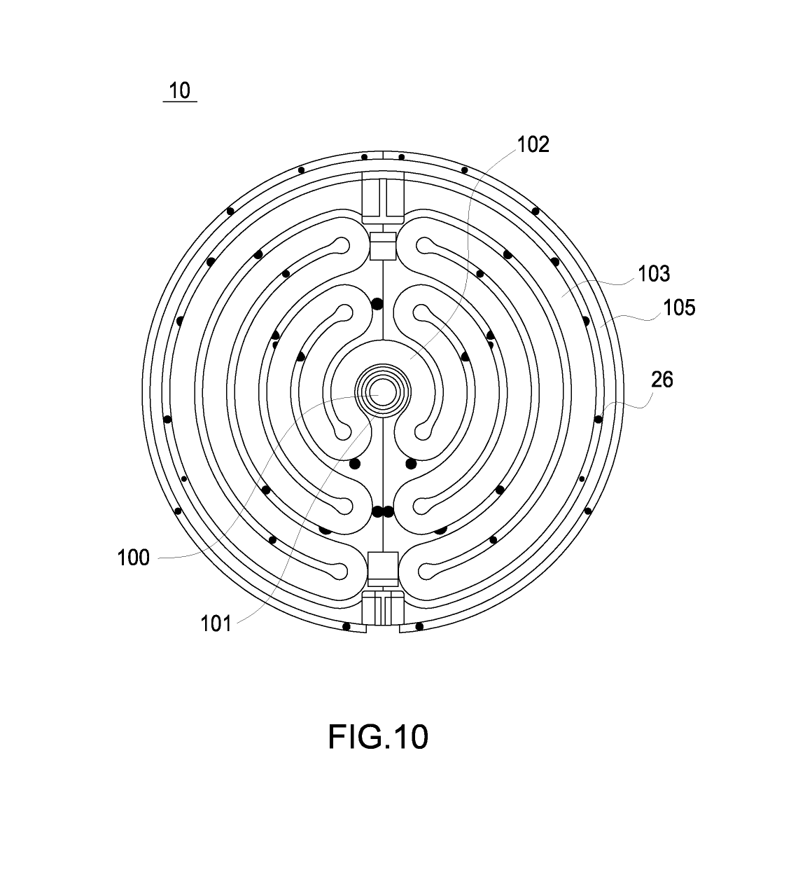

FIG. 10 illustrates a top view of a heater 10 in accordance with an embodiment of the present application. The heater 10 comprises a second top surface 102 having a second center 100; an inner heater 101; and an outer heater 105 distant from the second center 100 of the second top surface 102 than the inner heater 101. In the embodiment, the heater 10 further comprises a middle heater 103 disposed between the inner heater 101 and the outer heater 105. The second center 100 of the heater 10 is corresponding to the first center 92 of the susceptor 9 shown in FIG. 9. The shape of the outer heater 105, the middle heater 103, or the inner heater 101 is approximately a circle. The outer heater 105, the middle heater 103 and the inner heater 101 are substantially concentric. The outer heater 105 has a diameter larger than a diameter of the inner heater 101 or a diameter of the middle heater 103. An average temperature of the inner heater 101 is lower than an average temperature of the middle heater 103 or the outer heater 105 when the heater 10 is at on state.

The first group of wafer carriers 40a is substantially corresponding to the inner heater 101 and the second group of wafer carriers 40b is substantially corresponding to the middle heater 103 or the outer heater 105. Specifically, the first supporting parts 906 of the first group of wafer carriers 40a are substantially corresponding to the inner heater 101. Because the average temperature of the inner heater 101 is lower than that of the outer heater 105, the first supporting parts 906 having a larger top-viewed surface than the second supporting part 905 helps to radiate heat across the wafer disposed on the wafer carriers 40a.

The apparatus for depositing the thin film further comprises a connecting part (not shown), such as a spindle, to connect the susceptor 9 shown in FIG. 9 and the heater 10 shown in FIG. 10. The connecting part is rotated at a rate relative to a central axis (not shown) of the susceptor 9, and the susceptor 9 is driven to rotate clockwise or counterclockwise by the connecting part when the apparatus is at on state.

The principle and the efficiency of the present application illustrated by the embodiments above are not the limitation of the application. Any person having ordinary skill in the art can modify or change the aforementioned embodiments. Therefore, the protection range of the rights in the application will be listed as the following claims.

What is claimed is:

1. An apparatus for depositing a thin film, comprising:
a susceptor, comprising:
a first top surface having a first center;
a first group of wafer carriers surrounding the first center; and
a second group of wafer carriers surrounding the first group of wafer carriers, wherein one of the first group of wafer carriers comprises a first supporting part and at least one second supporting part, and the first supporting part has a feature size larger than that of the at least one second supporting part.

2. The apparatus as claimed in claim 1, wherein the first group of wafer carriers and the second group of wafer carriers are arranged substantially concentric.

3. The apparatus as claimed in claim 1, wherein the feature size comprises a surface area.

4. The apparatus as claimed in claim 1, wherein the susceptor comprises a substantially flat bottom surface.

5. The apparatus as claimed in claim 1, wherein the first supporting part is closer to the first center of the first top surface than the at least one second supporting part.

6. The apparatus as claimed in claim 1, wherein the first supporting part is next to the first center.

7. The apparatus as claimed in claim 1, further comprising a heater comprising a second top surface having a second center.

8. The apparatus as claimed in claim 7, wherein the heater comprises an inner heater and an outer heater distant from the second center of the second top surface than the inner heater, and the inner heater and the outer heater are arranged substantially concentric.

9. The apparatus as claimed in claim 8, wherein the second center is corresponding to the first center, and the outer heater has a diameter larger than a diameter of the inner heater.

10. The apparatus as claimed in claim 8, wherein an average temperature of the inner heater is lower than an average temperature of the outer heater when the apparatus is at on state.

11. The apparatus as claimed in claim 8, wherein the first group of wafer carriers is substantially corresponding to the inner heater and the second group of wafer carriers is substantially corresponding to the outer heater.

12. The apparatus as claimed in claim 7, further comprising a connecting part connecting the susceptor and the heater.

13. The apparatus as claimed in claim 12, wherein the susceptor is driven to rotate by the connecting part when the apparatus is at on state.

14. The apparatus as claimed in claim 1, wherein the at least one second supporting part comprises a first side and a second side, wherein the first side comprises a first surface having a first curvature, and the second side comprises a second surface having a second curvature different from the first curvature.

15. The apparatus as claimed in claim 14, wherein the first supporting part has a shape different from the second supporting part.

16. The apparatus as claimed in claim 1, wherein one of the first group of wafer carriers comprises a plurality of second supporting parts, and one of the second group of wafer carriers comprises a plurality of third supporting parts.

17. The apparatus as claimed in claim 16, wherein an amount of the plurality of third supporting parts is larger than an amount of the plurality of second supporting parts.

18. The apparatus as claimed in claim 17, wherein the plurality of third supporting parts is located unevenly along a perimeter.

19. The apparatus as claimed in claim 1, wherein one of the first group of wafer carriers or one of the second group of wafer carriers comprise an opening having a bottom surface that is a curve.

20. The apparatus as claimed in claim 19, wherein a top view of the opening comprises an edge and a center, wherein the bottom surface comprises a convex surface having a height protruding from the edge of the opening to the center of the convex surface, or the bottom surface comprises a concave surface having a depth sinking from the edge of the opening to the center of the concave surface.
